(19) United States
(12) Patent Application Publication
(10) Pub. No.: US 2021/0133379 A1
(43) Pub. Date: May 6, 2021

(54) DESIGN ASSISTANCE SYSTEM AND DESIGN ASSISTANCE METHOD

(71) Applicant: NEC Corporation, Minato-ku, Tokyo (JP)

(72) Inventors: Ryusuke NEBASHI, Tokyo (JP); Toshitsugu SAKAMOTO, Tokyo (JP); Makoto MIYAMURA, Tokyo (JP); Yukihide TSUJI, Tokyo (JP); Ayuka TADA, Tokyo (JP); Xu BAI, Tokyo (JP)

(73) Assignee: NEC Corporation, Minato-ku, Tokyo (JP)

(21) Appl. No.: 16/478,517

(22) PCT Filed: Jan. 22, 2018
(86) PCT No.: PCT/JP2018/001823

§ 371 Date: Jul. 17, 2019

(30) Foreign Application Priority Data
Jan. 26, 2017 (JP) 2017-011975

(51) Int. Cl. G06F 30/31; G06F 30/394

(52) U.S. Cl. CPC G06F 30/31; G06F 30/394

(57) ABSTRACT

A design assistance system according to the present invention assists in designing a circuit to be mounted on a programmable logic integrated circuit including a resistance change element. The design assistance system includes: a memory; and at least one processor coupled to the memory. The processor performs operations. The operations includes: generating rewriting history information indicating a number (count) of changing times of a state of the resistance change element; calculating an abrasion cost of a switch included in the circuit, based on the rewriting history information; and carrying out wiring of the circuit, based on an evaluation function including the abrasion cost.

### TECHNICAL FIELD

The present invention relates to a design assistance system and a design assistance method that assist with a circuit design.

### BACKGROUND ART

A programmable logic integrated circuit such as a field programmable gate array (FPGA) is formed of a logical element, an input and output element, and a connection element. The logical element provides a programmable logic arithmetic function. As the logical element, for example, a logic block formed of a lookup table that achieves a combination circuit, a flip-flop that stores data, and a selector are used. The input and output element provides a programmable input and output function with respect to an outside of a device. The connection element provides a programmable connection function between logical elements and input and output elements. In this way, a user freely combines a plurality of logic blocks, and thus can form a desired logic circuit in the programmable logic integrated circuit. Information (configuration information) needed for forming a desired logic circuit is stored in a memory element provided in a programmable logic integrated circuit. A static random access memory (SRAM) cell, an anti-fuse, a floating gate metal-oxide-semiconductor (MOS) transistor, and the like are used for the memory element that stores the configuration information.

A switch that changeably connects these memory elements and logic blocks is generally formed in the same layer as that of a logic block formed of many transistors. This causes a great area overhead. In this way, a chip area of the programmable logic integrated circuit increases, and a manufacturing cost increases. Further, an increase in layout area of the memory element and the switch reduces a proportion of logic blocks accounting for the chip area.

Thus, a programmable logic integrated circuit using a resistance change element that can be formed in a wiring layer is proposed as a switch capable of changing a connection between logic blocks after manufacturing while suppressing an increase in layout area. For example, programmable logic integrated circuits described in Patent Literature (PTL) 1, PTL 2, and Non-Patent Literature (NPL) 1 have a configuration in which a resistance change element formed of a solid electrolytic material containing a metal ion is arranged between a first wiring layer and a second wiring layer formed above the first wiring layer. The resistance change element can be changed a resistance value by applying a bias voltage in a forward direction or a backward direction to both ends thereof, and a ratio of a low resistance state (on-state) to a high resistance state (off-state) is the fifth power of 10 or greater. In other words, the resistance change element functions as a switch that electrically connects or disconnects first wiring and second wiring.

An SRAM cell being a memory element and a switch cell including one transistor having a switch function are used for connection and disconnection of wiring in a widely used programmable logic integrated circuit. On the other hand, the resistance change element has both a memory function and a switch function, and thus one resistance change element can achieve a switch cell.

In a semiconductor device described in PTL 1, a resistance change element is arranged at each intersection of a first wiring group and a second wiring group intersecting the first wiring group. In this way, a crossbar switch capable of connecting or disconnecting any wire of the first wiring group and any wire of the second wiring group can be achieved in a compact size. As a result, an improvement in performance of a programmable logic integrated circuit by a great reduction in chip area and an improvement in use efficiency of a logic block can be expected.

Further, an on-state on or an off-state of the resistance change element is held even when a power supply to the programmable logic integrated circuit stops. Thus, there is also an advantage of being capable of saving time for loading configuration information every time a power turns on.

There are PTLs 4 to 6 as another related art document. A wiring method described in PTL 4 provides an adjacent spacing condition while narrowing down to a net having a problem, provides an adjacent spacing condition that does not violate wiring, based on a net list, and performs wiring processing. An optimum arrangement and wiring method described in PTL 5 searches for a path in which a delay of a designated clock signal is minimum, determines the path as an optimum position of a logic block, and acquires optimum wiring. An automatic layout method described in PTL 6 assigns a weight to wiring of a circuit, acquires a sum of products of a weight and a wiring length, and carries out wiring in such a way that the sum is minimum.

### CITATION LIST

### Patent Literature

[PTL 1] Japanese Patent No. 4356542
[PTL 2] International Patent Publication No. WO2012/043502
[PTL 3] Japanese Unexamined Patent Application Publication No. 2016-170703
[PTL 4] Japanese Unexamined Patent Application Publication No. 2006-155120
[PTL 5] Japanese Unexamined Patent Application Publication No. H08 (1996)-087537
[PTL 6] Japanese Unexamined Patent Application Publication No. H05 (1993)-082649

### Non Patent Literature

[NPL 1] M. Miyamura et al., “Low-power programmable-logic cell arrays using nonvolatile complementary atom switch”, 15th International symposium on Quality Electronic Design (ISQED), pp. 330-334, Mar. 3-5, 2014
[NPL 2] Xiao-Yu Hu, et al., “Write amplification analysis in flash-based solid state drives”, Proceedings of SYSTOR 2009: The Israeli Experimental Systems Conference (SYSTOR: ACM International Systems and Storage Conference), Article No. 10, pp. 1-9, 2009

### SUMMARY OF INVENTION

### Technical Problem

The resistance change element as mentioned above has a limited rewritable number of times. When the resistance change element is repeatedly rewritten, the resistance change element deteriorates, and rewriting cannot be performed in the end. Thus, when writing is concentrated on some resistance change elements, a programmable logic integrated circuit breaks down in an earlier stage, and a desired logic circuit cannot be formed.

A ware leveling technique for leveling writing to a memory is known as a related technique. For example, a solid-state drive (SSD) described in NPL 2 includes a controller and a flash memory. The controller converts an address of user data designated by a logical address, and writes the user data to a flash memory designated by a physical address.

Further, for example, PTL 3 describes a storage device that controls a correspondence between a logical address and a memory line in such a way as to distribute a writing destination in order to avoid deterioration of a memory cell due to repeated writing performed on the same memory line.

A technique described in NPL 2 can improve a degree of freedom of a physical position in which data are stored by address conversion. However, it is difficult to apply this technique, as it is, to a programmable logic integrated circuit. The reason is that data in the programmable logic integrated circuit define a logic arithmetic function of a logic block near a physical position in which the data are stored and a connection state between logic blocks, and thus a desired logic circuit cannot be formed when a physical position of some pieces of data is simply moved. The same holds true for the technique described in NPL 3, and the technique does not have consistency of a connection relationship between circuits.

An object of the present invention is to provide a design assistance system and a design assistance method that solve the above-described issue.

### Solution to Problem

A design assistance system according to one aspect of the present invention assists in designing a circuit to be mounted on a programmable logic integrated circuit including a resistance change element. The design assistance system includes:

rewriting-history-information generation means for generating rewriting history information indicating a number (count) of changing times of a state of the resistance change element;

abrasion-cost generation means for calculating an abrasion cost of a switch included in the circuit, based on the rewriting history information; and

wiring means for carrying out wiring of the circuit, based on an evaluation function including the abrasion cost.

A design assistance method according to one aspect of the present invention assists in designing a circuit to be mounted on a programmable logic integrated circuit including a resistance change element. The design assistance method includes:

generating rewriting history information indicating a number (count) of changing times of a state of the resistance change element;

calculating an abrasion cost of a switch included in the circuit, based on the rewriting history information; and

carrying out wiring of the circuit, based on an evaluation function including the abrasion cost.

### Advantageous Effects of Invention

As described above, a highly reliable programmable logic integrated circuit can be provided according to the present invention.

### BRIEF DESCRIPTION OF DRAWINGS

FIG. 1 is a diagram illustrating a first example embodiment of a design assistance system of the present invention.

FIG. 2 is a flowchart illustrating one example of a design assistance method in the design assistance system illustrated in FIG. 1.

FIG. 3 is a diagram illustrating a second example embodiment of a design assistance system of the present invention.

FIG. 4 is a diagram illustrating one configuration example of a design assistance tool group provided in the design assistance system illustrated in FIG. 3 in the second example embodiment.

FIG. 5 is a flowchart illustrating one example of a design assistance method in the design assistance system illustrated in FIG. 3.

FIG. 6A is a diagram illustrating a first example of an abrasion cost function when an abrasion-cost generation tool illustrated in FIG. 4 calculates an abrasion cost.

FIG. 6B is a diagram illustrating a second example of an abrasion cost function when the abrasion-cost generation tool illustrated in FIG. 4 calculates an abrasion cost.

FIG. 6C is a diagram illustrating a third example of an abrasion cost function when the abrasion-cost generation tool illustrated in FIG. 4 calculates an abrasion cost.

FIG. 7 is a flowchart illustrating one example of an arrangement and wiring procedure performed by an arrangement-and-wiring tool illustrated in FIG. 4.

FIG. 8 is a schematic diagram illustrating one example of two logic blocks and a wiring resource connecting the two logic blocks provided in a programmable logic integrated circuit illustrated in FIG. 3.

FIG. 9 is a directed graph illustrating an already-wired route and alternative wiring routes that are related to a connection request.

FIG. 10 is a diagram illustrating one example of an abrasion cost function F(N) indicating an abrasion cost with respect to the number N of rewriting times.

FIG. 11 is a flowchart illustrating one example of an arrangement and wiring procedure in a third example embodiment of a design assistance system of the present invention.

FIG. 12 is a flowchart illustrating one example of an arrangement and wiring procedure in a fourth example embodiment of a design assistance system of the present invention.

FIG. 13 is a diagram illustrating one configuration example of a design assistance tool group provided in the design assistance system illustrated in FIG. 3 in a fifth example embodiment.

FIG. 14 is a flowchart illustrating one example of a design assistance method in the fifth example embodiment.

FIG. 15A is a schematic diagram illustrating one example of a programmable logic integrated circuit on which a circuit A is mounted.

FIG. 15B is a schematic diagram illustrating one example of the programmable logic integrated circuit on which a circuit B is mounted based on configuration information.

FIG. 15C is a schematic diagram illustrating one example of the programmable logic integrated circuit when the circuit B is mounted based on revised configuration information after an equivalent circuit analysis.

### EXAMPLE EMBODIMENT

Hereinafter, example embodiments of the present invention are described with reference to drawings.

### First Example Embodiment

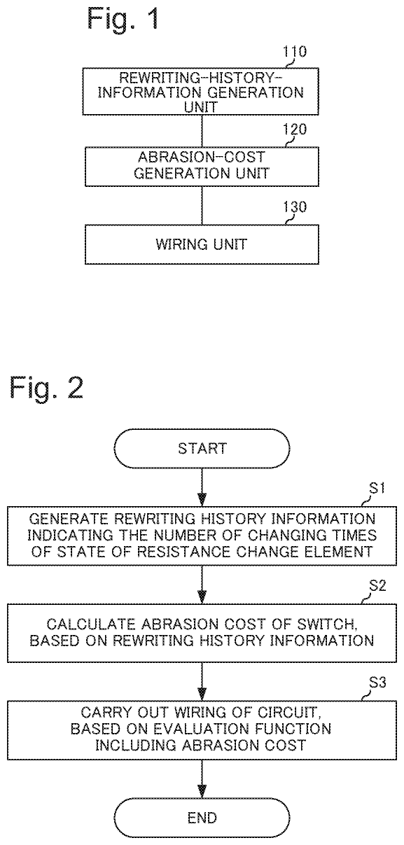

FIG. 1 is a diagram illustrating a first example embodiment of a design assistance system of the present invention. The design assistance system according to the present example embodiment assists in designing a circuit mounted on a programmable logic integrated circuit including a resistance change element. As illustrated in FIG. 1, the design assistance system according to the present example embodiment includes a rewriting-history-information generation unit 110, an abrasion-cost generation unit 120, and a wiring unit 130.

The rewriting-history-information generation unit 110 generates rewriting history information indicating the number of changing times of a state of a resistance change element. The abrasion-cost generation unit 120 calculates an abrasion cost of a switch included in a circuit, based on the rewriting history information generated by the rewriting-history-information generation unit 110. The wiring unit 130 carries out wiring of the circuit, based on an evaluation function including the abrasion cost.

Hereinafter, a design assistance method in the design assistance system illustrated in FIG. 1 is described. FIG. 2 is a flowchart illustrating one example of the design assistance method in the design assistance system illustrated in FIG. 1.

First, the rewriting-history-information generation unit 110 generates rewriting history information indicating the number of changing times of a state of a resistance change element provided in a programmable logic integrated circuit (Step S1). Then, the abrasion-cost generation unit 120 calculates an abrasion cost of a switch included in a circuit mounted on the programmable logic integrated circuit, based on the rewriting history information generated by the rewriting-history-information generation unit 110 (Step S2). Next, the wiring unit 130 carries out wiring of the circuit mounted on the programmable logic integrated circuit, based on an evaluation function including the abrasion cost (Step S3).

In this way, the first example embodiment calculates an abrasion cost, based on the number of changing times of a state of a resistance change element, and carries out wiring of a circuit, based on an evaluation function including the abrasion cost. Thus, the first example embodiment can provide a highly reliable programmable logic integrated circuit.

### Second Example Embodiment

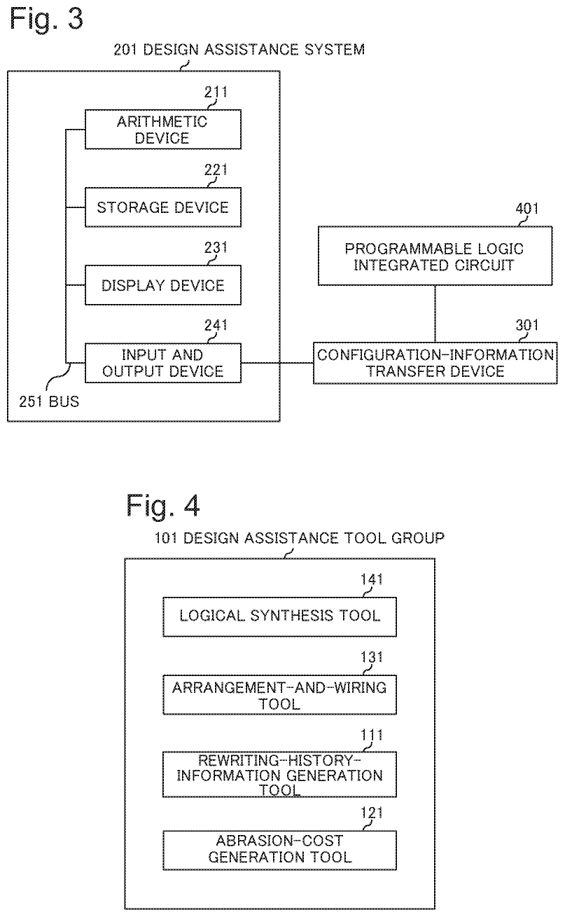

FIG. 3 is a diagram illustrating a second example embodiment of the design assistance system of the present invention. As illustrated in FIG. 3, a design assistance system 201 according to the present example embodiment is connected to a configuration-information transfer device 301. Further, the design assistance system 201 is connected to a programmable logic integrated circuit 401 via the configuration-information transfer device 301. These connections may use a wired manner, or may use a wireless manner. Further, a communication method of a signal in the connections is not particularly restricted. Note that the programmable logic integrated circuit 401 and the configuration-information transfer device 301 may be installed in the design assistance system 201 as application boards.

The design assistance system 201 is achieved by, for example, by a computer system. As illustrated in FIG. 3, the design assistance system 201 includes an arithmetic device 211, a storage device 221, a display device 231, and an input and output device 241. The arithmetic device 211, the storage device 221, the display device 231, and the input and output device 241 are connected to each other via a bus 251.

The arithmetic device 211 controls an operation of the entire design assistance system 201 by performing processing according to a program previously stored in the storage device 221. Further, the arithmetic device 211 achieves a function of a design assistance tool group, which is described later, by performing processing according to a program previously stored in the storage device 221.

The storage device 221 is a storage medium such as a memory that stores design information and a program. The design information includes operation description information, restriction condition information, and the like for a circuit that is mounted on the programmable logic integrated circuit 401 and is created by a designer. The design information includes net list information, arrangement and wiring information, resource information and configuration information for the programmable logic integrated circuit 401, rewriting history information, and the like, which are processing results by the arithmetic device 211 described later.

The display device 231 displays an instruction input screen of a design assistance tool and a processing result performed by the design assistance tool. The display device 231 displays information about the number of rewriting times of a resistance change element described later and an abrasion cost. As a display method, a graph display of data after statistical processing and a color display on a floor planner are included. By checking these displays, for example, a user can create a floor plan to avoid where the number of rewriting times (the number of changing times) is large.

The input and output device 241 is an interface circuit that transmits and receives a signal and data to and from an input device, such as a keyboard, a mouse, and a touch panel, and the configuration-information transfer device 301, and an output device such as a printing device. The input and output device 241 provides a function of setting an abrasion cost described later to a user. By using this function, the user can set wiring that gives priority to a delay time and an area, or wiring that minimizes an abrasion. Further, the input and output device 241 provides a function of setting a threshold number of times of an abrasion cost function that changes in a step described later to a user. By using this function, the user can set wiring that gives priority to a delay time and an area, or wiring that minimizes an abrasion.

The configuration-information transfer device 301 is connected to the design assistance system 201 and the programmable logic integrated circuit 401, and controls transmission of data such as configuration information between the design assistance system 201 and the programmable logic integrated circuit 401. For example, the configuration-information transfer device 301 receives data such as configuration information transmitted from the design assistance system 201, converts the data into transmission data according to a specification of data input and output for the programmable logic integrated circuit 401, and transfers the transmission data. Further, the configuration-information transfer device 301 receives data such as configuration information output from the programmable logic integrated circuit 401, converts the data into transmission data according to a specification of data input and output for the design assistance system 201, and transfers the transmission data.

FIG. 4 is a diagram illustrating one configuration example of a design assistance tool group provided in the design assistance system 201 illustrated in FIG. 3 according to the second example embodiment. As illustrated in FIG. 4, in the present example embodiment, a design assistance tool group 101 provided in the design assistance system 201 illustrated in FIG. 3 includes a rewriting-history-information generation tool 111, an abrasion-cost generation tool 121, an arrangement-and-wiring tool 131, and a logical synthesis tool 141. These tools are previously stored in the storage device 221 illustrated in FIG. 3, and read from the storage device 221 and then executed by the arithmetic device 211.

The logical synthesis tool 141 is a logical synthesis unit that performs a logical synthesis of a circuit by referring to operation description information and restriction condition information for a delay and power, which are input by a designer using the input and output device 241. The designer can acquire a net list by using the logical synthesis tool 141. The net list is generated by using a logical element provided in the programmable logic integrated circuit 401. The net list is connection information for a logical element and between logical elements.

The arrangement-and-wiring tool 131 is an arrangement unit and a wiring unit. The arrangement-and-wiring tool 131 generates resource information for a logical element, a wiring resource, and the like of the programmable logic integrated circuit 401.

The arrangement-and-wiring tool 131 virtually arranges and wires logical elements included in the net list, based on the resource information of the programmable logic integrated circuit 401. A designer can acquire configuration information by using the arrangement-and-wiring tool 131.

The rewriting-history-information generation tool 111 is a rewriting history-information-generation unit that generates device-unique rewriting history information, based on the configuration information read from the programmable logic integrated circuit 401. The rewriting history information includes address information being a state of a resistance change element included in a logical element and a connection element provided in the programmable logic integrated circuit 401, and rewriting time number information indicating the number of changing times (rewriting times).

The abrasion-cost generation tool 121 is an abrasion-cost generation unit that generates a device-unique abrasion cost of a switch and the like included in a circuit, based on the rewriting history information generated by the rewriting-history-information generation unit 111. The abrasion-cost generation tool 121 calculates an abrasion cost by using an abrasion cost function F(N) with respect to the number N of rewriting times. The abrasion cost is supplied to the arrangement-and-wiring tool 131, and is used for next arrangement and wiring.

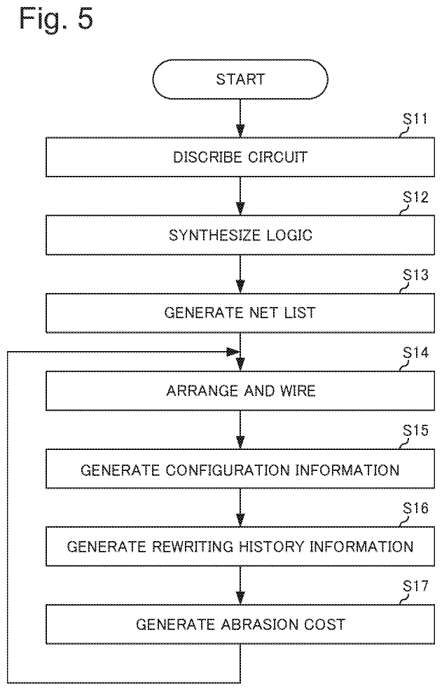

Hereinafter, a design assistance method according to the design assistance system 201 illustrated in FIG. 3 is described. FIG. 5 is a flowchart illustrating one example of the design assistance method according to the design assistance system 201 illustrated in FIG. 3. The design assistance system 201 illustrated in FIG. 3 successively performs a logical synthesis process, an arrangement and wiring process, a rewriting history generation process, and an abrasion cost generation process. Herein, processing, in the case where a circuit B different from a circuit A is mounted on the programmable logic integrated circuit 401 on which the circuit A has already been mounted, is described.

First, an operation description file of the circuit B created by a designer by using a hardware description language such as a Verilog-hardware description language (HDL) or a very high-speed integrated circuit hardware description language (VHDL) is input to the design assistance system 201 by using the input and output device 241 (Step S11).

The logical synthesis tool 141 performs a logical synthesis on the input operation description file (Step S12), and generates a net list (Step S13). The net list is generated by using a logical element provided in the programmable logic integrated circuit 401. The logical synthesis tool 141 optimizes a circuit in such a way as to satisfy timing restriction information previously set by the designer.

Next, the arrangement-and-wiring tool 131 performs arrangement and wiring processing of the circuit mounted on the programmable logic integrated circuit 401 (Step S14), and generates configuration information (Step S15). The arrangement-and-wiring tool 131 has a characteristic of performing the arrangement and wiring processing, based on an abrasion cost described later.

When configuration information of the circuit B is determined, the configuration-information transfer device 301 is connected to the design assistance system 201 and the programmable logic integrated circuit 401, based on an operation of the designer to the input and output device 241. In this way, communication routes to the design assistance system 201 and the programmable logic integrated circuit 401 are established. The determined configuration information is transmitted from the design assistance system 201 to the programmable logic integrated circuit 401 via the configuration-information transfer device 301. When receiving the configuration information from the configuration-information transfer device 301, the programmable logic integrated circuit 401 starts a configuration operation. When the configuration operation of all the configuration information is completed, the programmable logic integrated circuit 401 is in a state in which the circuit B is mounted.

Then, the rewriting-history-information generation unit 111 generates rewriting history information that includes address information of each resistance change element provided in the programmable logic integrated circuit 401 and information indicating the number of rewriting times of a state of each resistance change element (Step S16). The rewriting-history-information generation tool 111 compares configuration information (circuit B) read from the programmable logic integrated circuit 401 after the configuration with configuration information of the circuit A, and updates the rewriting history information by taking a difference between the pieces of configuration information. Note that the rewriting-history-information generation tool 111 previously acquires the configuration information of the circuit A by such as to read out the configuration of the configuration information of the circuit B and the like in advance.

Next, the abrasion-cost generation tool 121 generates an abrasion cost including the address information for each resistance change element and information indicating an abrasion cost of each resistance change element, based on the rewriting history information (Step S17). The generated abrasion cost is supplied to the arrangement-and-wiring tool 131, and is used for next arrangement and wiring.

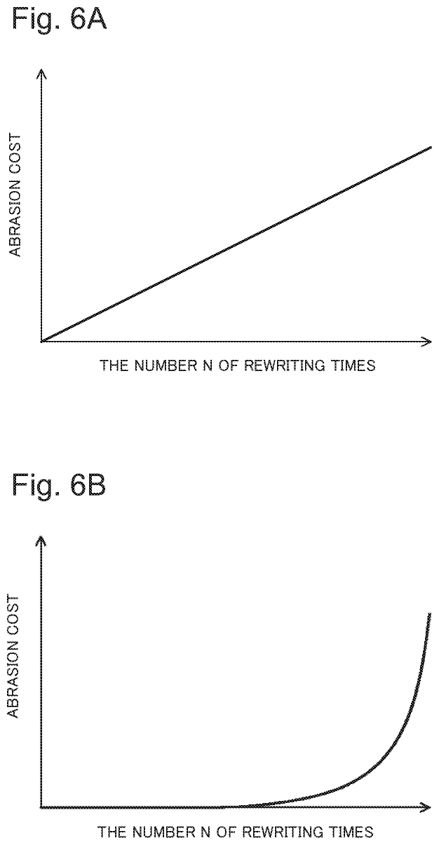

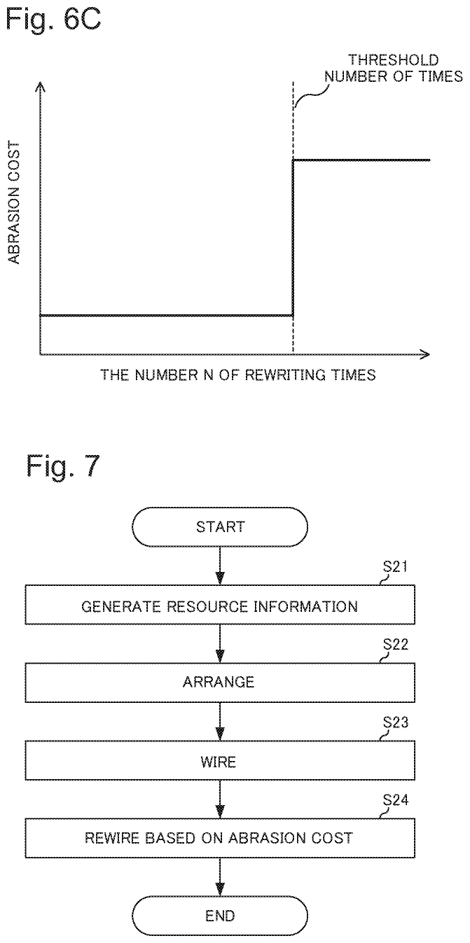

FIG. 6A is a diagram illustrating a first example of an abrasion cost function when the abrasion-cost generation tool 121 illustrated in FIG. 4 calculates an abrasion cost. FIG. 6A illustrates an abrasion cost function in which an abrasion cost gets greater (increases) with the number of rewriting times. As the abrasion cost function, a rate of failures of a resistance change element or a value in which a rate of failures is scaled to a value comparable with a delay cost or a congestion cost described later may be used. Herein, the rate of failures is a proportion of failures, in next rewriting, of resistance change elements that have been operated until a certain number N of rewriting times. One example of the abrasion cost function illustrated in FIG. 6A is a failure rate function of a Weibull distribution when a shape parameter is greater than 1. A failure rate function k(t) for the Weibull distribution is generally given by an equation of

λ(t)=(m/η\hat{ }m)t\hat{ }(m−1).

In this equation, m is referred to as a shape parameter (Weibull coefficient), and η is referred to as a scale parameter.

FIG. 6B is a diagram illustrating a second example of an abrasion cost function when the abrasion-cost generation tool 121 illustrated in FIG. 4 calculates an abrasion cost. FIG. 6B illustrates an abrasion cost function including a section in which an abrasion cost increases downward in a convexity with respect to the number of rewriting times. As the abrasion cost function, a rate of failures of a resistance change element or a value in which a rate of failures is scaled to a value comparable with a delay cost or a congestion cost described later may be used. One example of the abrasion cost function illustrated in FIG. 6B is a failure rate function of a Weibull distribution when a shape parameter is greater than 2.

An advantage of using a rate of failures of a resistance change element or a value in which a rate of failures is scaled to a value comparable with a delay cost or a congestion cost described later, as the abrasion cost function, is that an evaluation function in arrangement and wiring can be associated with a rate of failures of the programmable logic integrated circuit 401.

Herein, a failure of the programmable logic integrated circuit 401 is defined as a failure of one resistance change element among a plurality of resistance change elements constituting the programmable logic integrated circuit 401. Such a system is a series system in terms of reliability. A rate of failures of the entire series system is a sum of rates of failures of components. Thus, by setting an evaluation function in the arrangement and wiring as a sum of abrasion costs, the evaluation function can be associated with a rate of failures of the programmable logic integrated circuit 401. A rate of failures of the programmable logic integrated circuit 401 can be minimized by minimizing the evaluation function in the arrangement and wiring.

FIG. 6C is a diagram illustrating a third example of an abrasion cost function when the abrasion-cost generation tool 121 illustrated in FIG. 4 calculates an abrasion cost. FIG. 6C illustrates an abrasion cost function in which an abrasion cost changes in a step with respect to the number of rewriting times. Herein, the number of rewriting times at which an abrasion cost changes is defined as a threshold number of times. A value comparable with a delay cost or a congestion cost is used as an abrasion cost in a smaller number of rewriting times than a threshold number of times. A greater value than that of a delay cost and a congestion cost may be set to an abrasion cost in a greater number of rewriting times than a threshold number of times.

The abrasion-cost generation tool 121 or the arrangement-and-wiring tool 131 may set a threshold number of times according to the number of times the configuration is performed on the programmable logic integrated circuit 401. Further, the abrasion-cost generation tool 121 or the arrangement-and-wiring tool 131 may set a threshold number of times according to a position of a resistance change element in the programmable logic integrated circuit 401. In the arrangement and wiring process, the abrasion-cost generation tool 121 or the arrangement-and-wiring tool 131 may set a threshold number of times, based on information of a wiring result such as the number of resistance change elements that require rewriting for greater than a threshold number of times of the arrangement and wiring process, whether wiring is enabled, and a delay time.

An advantage of using a step function as an abrasion cost function is that control according to a result of arrangement and wiring is easily performed. Further, the use of an element for greater than or equal to the number of rewriting guarantee times can be prohibited by setting a threshold number of times as the number of rewriting guarantee times of a resistance change element and setting an abrasion cost in a greater number of rewriting times than the threshold number of times to a sufficiently great value. Further, the use of a faulty resistance change element can be prohibited by setting a threshold number of times of the faulty resistance change element to zero and setting an abrasion cost in a greater number of rewriting times than the threshold number of times to a sufficiently great value.

FIG. 7 is a flowchart illustrating one example of an arrangement and wiring procedure performed by the arrangement-and-wiring tool 131 illustrated in FIG. 4. The arrangement-and-wiring tool 131 successively performs a resource information generation process, an arrangement process, a wiring process, and a rewiring process based on an abrasion cost.

The arrangement-and-wiring tool 131 generates resource information for a logical element, a wiring resource, and the like in the resource information generation process (Step S21). The resource information may include information as a set of an identification number of a certain logical element and an identification number of a resistance change element that stores configuration information of the logical element. Further, the resource information may include, as information linked to an identification number of a certain wiring resource and an identification number of a resistance change element connected to the wiring resource, a directed graph or a non-directed graph of the wiring resource, for example. Further, an abrasion cost of each resistance change element may be acquired by associating an identification number of a resistance change element with address information.

The arrangement-and-wiring tool 131 assigns each logical element included in a net list to an arrangement slot of the programmable logic integrated circuit 401 in the arrangement process (Step S22). The slot is a place where a logical element is arranged. The arrangement-and-wiring tool 131 uses, for example, a sum of virtual wiring lengths as an evaluation value (evaluation function), and searches for arrangement that minimizes the evaluation value. Herein, a virtual wiring length of a net is a sum of lengths in an x-axis direction and a y-axis direction of a rectangle which surrounds slot positions of all logical elements included in the net.

The arrangement-and-wiring tool 131 determines which wiring resource each logical element included in the net list uses to connect in the wiring process (Step S23). For example, the arrangement-and-wiring tool 131 uses an evaluation function including a delay cost and a congestion cost, and searches for wiring that minimizes the evaluation function, in order to achieve the minimization of a delay time and prevention of failing to find a wiring route. Herein, the delay cost is calculated based on a delay time of a wiring route. The congestion cost is calculated based on the number of nets competing against a certain wiring resource. The arrangement-and-wiring tool 131 repeatedly carries out wiring while gradually increasing a congestion cost, and thus the competition is resolved. When the competition is not resolved, the arrangement-and-wiring tool 131 may perform another procedure such as logical replication.

In the rewiring process based on the abrasion cost, the arrangement-and-wiring tool 131 performs an evaluation on an already-wired route and an alternative route of each net by using an evaluation function including an abrasion cost, and carries out rewiring (Step S24). Herein, the alternative route is searched in a range that does not affect a wiring route of another net.

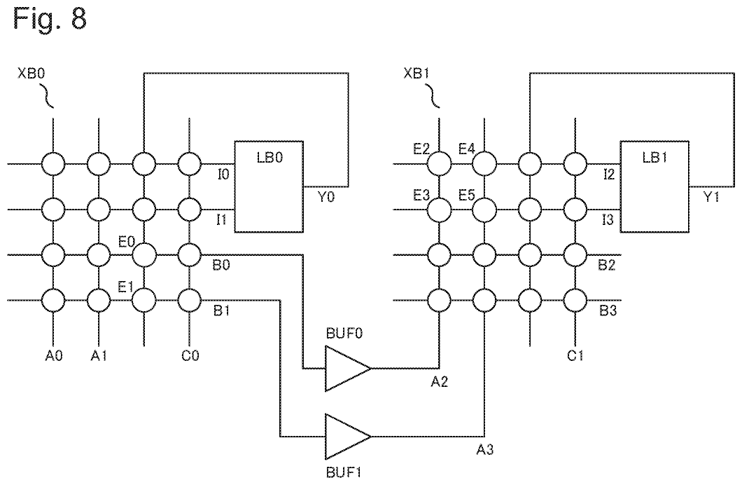

Hereinafter, wiring processing based on an abrasion cost is described. FIG. 8 is a schematic diagram illustrating one example of two logic blocks and a wiring resource connecting the two logic blocks provided in the programmable logic integrated circuit 401 illustrated in FIG. 3. A logic block as a logical element illustrated in FIG. 8 includes two input terminals and one output terminal. A wiring resource illustrated in FIG. 8 is formed of two crossbar switches and two buffer circuits.

The crossbar switch is formed of four column wires extending in a column direction, four row wires extending in a row direction, and resistance change elements located at intersecting portions of the column wires and the row wires. The crossbar switch can connect or disconnect any wire of the column wires and any wire of the row wires by using the resistance change element.

A crossbar switch XB0 uses column wires A0 and A1 as input lines, connects a column wire Y0 to an output terminal of a logic block LB0, and grounds a column wire C0. The crossbar switch XB0 uses row wires I0 and I1 as output lines, and connects them to input terminals of the logic block LB0. The crossbar switch XB0 uses row wires B0 and B1 as output wires, and connects them to input terminals of buffer circuits BUF0 and BUF1, respectively.

A crossbar switch XB1 uses column wires A2 and A3 as input lines, and connects them to output terminals of the buffer circuits BUF0 and BUF1, respectively. The crossbar switch XB1 connects a column wire Y1 to an output terminal of a logic block LB1, and grounds a column wire Cl. The crossbar switch XB1 uses row wires 12 and 13 as output lines, and connects them to input terminals of the logic block LB1. The crossbar switch XB1 uses row wires B2 and B3 as output wires.

Herein, it is consider that the arrangement-and-wiring tool 131 has already carried out wiring, as an already-wired route, in order of the wire Y0, a resistance change element E0, the wire B0, the buffer circuit BUF0, the wire A2, a resistance change element E2, and the wire 12, according to a connection request from the output terminal Y0 of LB0 to one of the input terminals 12 and 13 of LB1, in the wiring process. When performing wiring processing, based on an abrasion cost, the arrangement-and-wiring tool 131 searches for an alternative route, based on a wiring resource graph. Herein, related resistance change elements are E0, E1, E2, E3, E4, and E5.

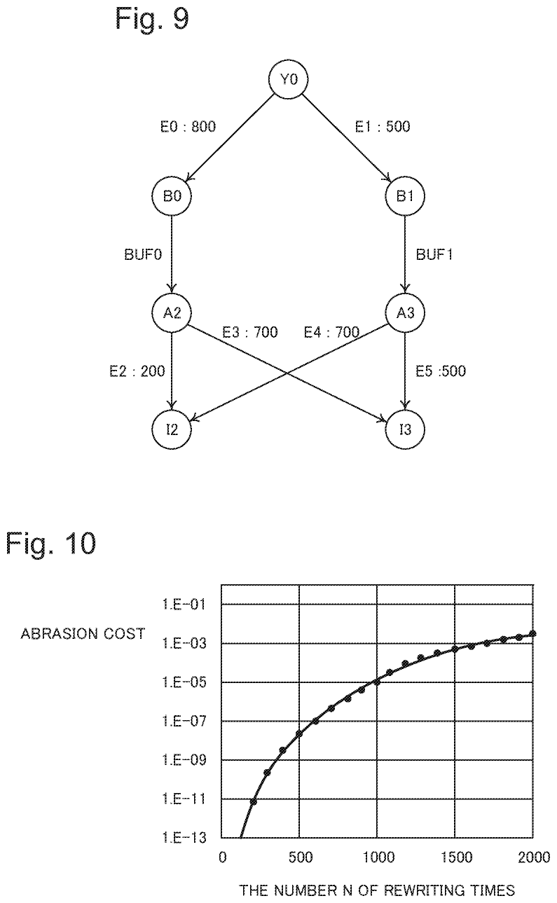

FIG. 9 is a directed graph illustrating an already-wired route and alternative wiring routes that are related to a connection request. In FIG. 9, a node indicated by a circle represents a wire, and an edge indicated by a solid line with an arrow represents a resistance change element or a buffer circuit. The edge is provided with the number of rewriting times of the resistance change element.

In FIG. 9, there are three alternative wiring routes. An alternative wiring route 1 is a wiring route formed of the wire Y0, the resistance change element E0, the wire B0, the buffer circuit BUF0, the wire A2, the resistance change element E3, and the wire 13. An alternative wiring route 2 is a wiring route formed of the wire Y0, the resistance change element E1, the wire B1, the buffer circuit BUF1, the wire A3, the resistance change element E4, and the wire 12. An alternative wiring route 3 is a wiring route formed of the wire Y0, the resistance change element E1, the wire B1, the buffer circuit BUF1, the wire A3, the resistance change element E5, and the wire 13.

When one resistance change element is included in a wiring route, it is considered to be a rational method to prioritize a wiring route via a resistance change element having the smallest number of rewriting times as a method of distributing rewriting of a resistance change element. However, when a plurality of resistance change elements are included in a wiring route, the method of distributing rewriting of a resistance change element is not always obvious.

With reference to FIG. 9, the resistance change element having the smallest number of rewriting times is E2, and thus the already-wired route including E2 is considered to be one of optimum candidates. However, there is a disadvantage that the already-wired route includes the resistance change element E0 having the greatest number of rewriting times. Therefore, when a plurality of resistance change elements are included in a wiring route, a method of appropriately selecting a wiring route is also needed.

As the method of distributing rewriting of a resistance change element, the arrangement-and-wiring tool 131 carries out wiring, based on an evaluation function including an abrasion cost, in the present invention. For example, the arrangement-and-wiring tool 131 adopts the smallest sum of abrasion costs of resistance change elements included in a wiring route.

FIG. 10 is a diagram illustrating one example of an abrasion cost function F(N) indicating an abrasion cost with respect to the number N of rewriting times. Herein, a rate of failures based on a Weibull distribution is used as the abrasion cost function F(N). In the example illustrated in FIG. 10, it is assumed that a shape parameter is 10, and an average number of rewritable times is 2000. In this case, a sum of abrasion costs in the already-wired route is 1E-6, a sum of abrasion costs in the alternative wiring route 1 is 2E-6, a sum of abrasion costs in the alternative wiring route 2 is 4.1E-7, and an abrasion cost in the alternative wiring route 3 is 3.8E-8. The sum of the abrasion costs in the alternative wiring route 3 is the smallest, and thus the arrangement-and-wiring tool 131 selects the alternative wiring route 3 as an alternative wiring route.

As described above, the design assistance system 201 for assisting in designing a circuit mounted on the programmable logic integrated circuit 401 including a resistance change element according to the present example embodiment can level the number of rewriting times of the resistance change element of the programmable logic integrated circuit 401. Furthermore, the design assistance system 201 carries out wiring, based on an evaluation function including an abrasion cost. In this way, even when a plurality of resistance change elements are included in a wiring route, it is possible to select a wiring route appropriately. Therefore, according to the present example embodiment, it is possible to provide a highly reliable programmable logic integrated circuit.

### Third Example Embodiment

Hereinafter, a third example embodiment of the design assistance system of the present invention is described. A configuration of the design assistance system in the present example embodiment is similar to that in the second example embodiment, and thus a component thereof is described by using the component illustrated in FIGS. 3 and 4.

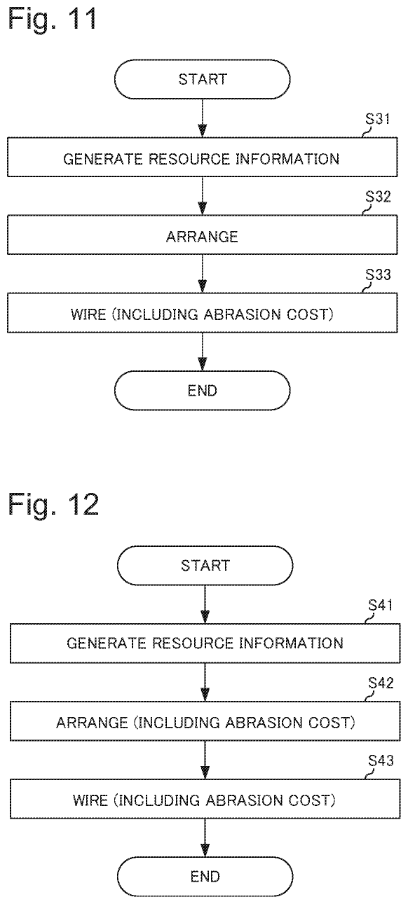

Hereinafter, an arrangement and wiring procedure in the third example embodiment of the design assistance system of the present invention is described. FIG. 11 is a flowchart illustrating one example of the arrangement and wiring procedure according to the third example embodiment of the design assistance system of the present invention. An arrangement-and-wiring tool 131 successively performs a resource information generation process, an arrangement process, and a wiring process with consideration given to an abrasion cost. The resource information generation process (Step S31) and the arrangement process (Step S32) in the arrangement and wiring procedure according to the present example embodiment are the same as those in the second example embodiment, and thus description thereof is omitted.

The arrangement-and-wiring tool 131 determines which wiring resource each logical element included in a net list uses to connect in the wiring process with consideration given to an abrasion cost (Step S33). The arrangement-and-wiring tool 131 uses an evaluation function including an abrasion cost in addition to a delay cost and a congestion cost, and searches for wiring that minimizes the evaluation function. Herein, the delay cost is calculated based on a delay time of a wiring route. The congestion cost is calculated based on the number of nets competing against a certain wiring resource. The abrasion cost is generated by using the abrasion-cost generation tool 121 similarly to the second example embodiment. The arrangement-and-wiring tool 131 repeatedly carries out wiring while gradually increasing a congestion cost, and thus the competition is resolved. When the competition is not resolved, the arrangement-and-wiring tool 131 may perform another procedure such as logical replication and revision of an abrasion cost.

As described above, the design assistance system 201 for assisting in designing a circuit mounted on the programmable logic integrated circuit 401 including a resistance change element according to the present example embodiment can level rewriting of the resistance change element of the programmable logic integrated circuit 401. Furthermore, the design assistance system 201 of the present example embodiment collectively carries out wiring by using an evaluation function including a delay cost, a congestion cost, and an abrasion cost. Therefore, it is possible to increase wiring route options compared with the second example embodiment, and to select a more appropriate wiring route.

### Fourth Example Embodiment

Hereinafter, a fourth example embodiment of the design assistance system of the present invention is described. A configuration of the design assistance system in the present example embodiment is similar to that in the second example embodiment, and thus a component thereof is described by using the component illustrated in FIGS. 3 and 4.

Hereinafter, an arrangement and wiring procedure in the fourth example embodiment of the design assistance system of the present invention is described. FIG. 12 is a flowchart illustrating one example of the arrangement and wiring procedure according to the fourth example embodiment of the design assistance system of the present invention. An arrangement-and-wiring tool 131 successively performs a resource information generation process, an arrangement process with consideration given to an abrasion cost, and a wiring process with consideration given to an abrasion cost. The resource information generation process (Step S41) and the wiring process with consideration given to an abrasion cost (Step S43) in the arrangement and wiring procedure according to the present example embodiment are the same as those in the third example embodiment, and thus description thereof is omitted.

The arrangement-and-wiring tool 131 assigns each logical element included in a net list to an arrangement slot of a programmable logic integrated circuit 401 in the arrangement process. The arrangement-and-wiring tool 131 uses an evaluation function formed of a sum of virtual wiring lengths and a congestion cost, and searches for arrangement that minimizes the evaluation function. Herein, for example, the congestion cost is calculated based on the number of wiring routes in which a delay time or an abrasion cost of each wiring route is less than or equal to a certain reference value among wiring routes that can be wired from a certain arrangement slot to another arrangement slot. The congestion cost is set in such a way as to increase with a smaller number of wiring routes. In this way, a wiring route including a resistance change element with a high abrasion cost is less likely to be included in the number of wiring routes, and thus a congestion cost increases. When a congestion cost between some arrangement slots increases, the arrangement-and-wiring tool 131 may search for alternative arrangement having a smaller evaluation function.

As described above, the design assistance system 201 for assisting in designing a circuit mounted on the programmable logic integrated circuit 401 including a resistance change element according to the present example embodiment can level rewriting of the resistance change element of the programmable logic integrated circuit 401. Furthermore, the design assistance system 201 in the present example embodiment calculates a congestion cost of wiring between arrangement slots, based on a delay time or an abrasion cost, and minimizes an evaluation function formed of a sum of virtual wiring lengths and the congestion cost. Therefore, it is possible to select optimum arrangement that levels rewriting of a resistance change element.

### Fifth Example Embodiment

Hereinafter, a fifth example embodiment of the design assistance system of the present invention is described. A configuration of the design assistance system in the present example embodiment is similar to that in the second example embodiment, and thus a component thereof is described by using the component illustrated in FIG. 3.

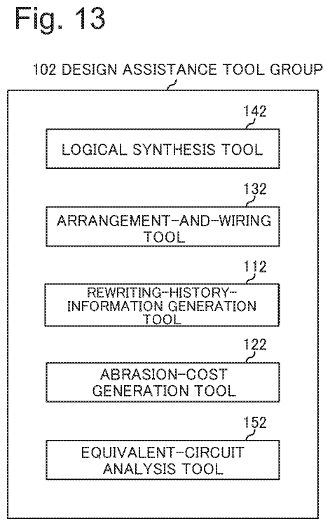

FIG. 13 is a diagram illustrating one configuration example of a design assistance tool group provided in the design assistance system 201 illustrated in FIG. 3 in the fifth example embodiment. As illustrated in FIG. 13, a design assistance tool group 102 provided in the design assistance system 201 illustrated in FIG. 3 in the present example embodiment includes a rewriting-history-information generation tool 112, an abrasion-cost generation tool 122, an arrangement-and-wiring tool 132, a logical synthesis tool 142, and an equivalent-circuit analysis tool 152. These tools are previously stored in the storage device 221 illustrated in FIG. 3, and read from the storage device 221 and then executed by the arithmetic device 211.

The logical synthesis tool 142, the arrangement-and-wiring tool 132, the rewriting-history-information generation tool 112, and the abrasion-cost generation tool 122 of the design assistance tool group 102 according to the fifth example embodiment illustrated in FIG. 13 are respectively similar to the logical synthesis tool 141, the arrangement-and-wiring tool 131, the rewriting-history-information generation tool 111, and the abrasion-cost generation tool 121 of the design assistance tool group 101 according to the second example embodiment illustrated in FIG. 4, and thus description thereof is omitted. Herein, processing, in the case where a circuit B different from a circuit A is mounted on a programmable logic integrated circuit 401 on which the circuit A has already been mounted, is described.

The equivalent-circuit analysis tool 152 performs optimization in such a way as to reduce unnecessary rewriting, based on configuration information of the circuit A being already mounted on the programmable logic integrated circuit 401 and configuration information of the circuit B output from the arrangement-and-wiring tool 132, and outputs the configuration information of the circuit B after revision.

The optimization is performed as follows. First, the equivalent-circuit analysis tool 152 calculates a total number of resistance change elements in which rewriting occurs when the circuit A is changed to the circuit B as a first count number, based on the configuration information of the circuit A and the configuration information of the circuit B. Next, the equivalent-circuit analysis tool 152 revises the configuration information of the circuit B, and generates configuration information of a circuit equivalent to the circuit B. The equivalent-circuit analysis tool 152 calculates a total number of resistance change elements in which rewriting occurs when the circuit A is changed to the circuit equivalent to the circuit B as a second count number, based on the configuration information of the circuit A and the configuration information of the circuit equivalent to the circuit B. When the second count number is less than the first count number, the equivalent-circuit analysis tool 152 outputs the configuration information of the circuit equivalent to the circuit B.

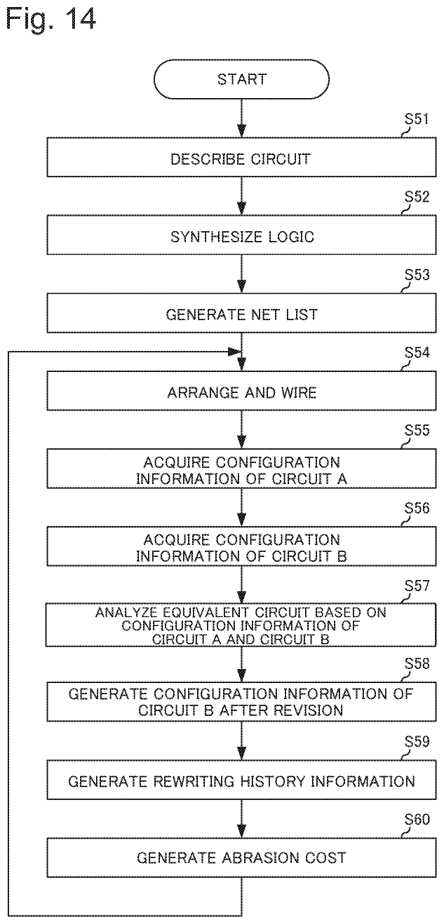

Hereinafter, a design assistance method according to the present example embodiment is described. FIG. 14 is a flowchart illustrating one example of the design assistance method according to the fifth example embodiment. The design assistance system 201 according to the fifth example embodiment successively performs a logical synthesis process, an arrangement and wiring process, an equivalent circuit analysis process, a rewriting history generation process, and an abrasion cost generation process. The logical synthesis process (Steps S51 to S52), the arrangement and wiring process (Steps S53 to S54), the rewriting history generation process (Step S59), and the abrasion cost generation process (Step S60) of the design assistance method (logical design procedure) according to the fifth example embodiment are similar to the processing in the second example embodiment, and thus description thereof is omitted.

The equivalent-circuit analysis tool 152 acquires configuration information of a circuit A and configuration information of a circuit B output from the arrangement-and-wiring tool 132 (Steps S55 to S56). The equivalent-circuit analysis tool 152 performs optimization in such a way as to reduce unnecessary rewriting, based on the acquired configuration information of the circuit A and the acquired configuration information of the circuit B, and outputs the configuration information of the circuit B after revision (Steps S57 to S58). An arrangement-and-wiring tool generally determines which wiring resource each logical element included in a net list uses to connect in the wiring process. However, the arrangement-and-wiring tool generally does not perform optimization in such a way as to reduce unnecessary rewriting on a wiring resource that is not to be used, a don't-care-bit of a logic block, and the like. Herein, the don't-care-bit is a bit that does not change a logical function achieved by a logic block even is a value of the bit is changed. The equivalent-circuit analysis tool 152 analyzes an equivalent circuit for such an unused wiring resource and a don't-care-bit of a logic block, and performs optimization in such a way as to reduce unnecessary rewriting.

Hereinafter, the equivalent circuit analysis process is described with specific examples.

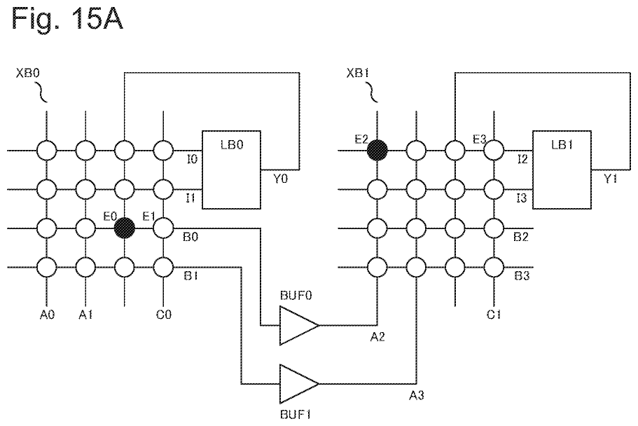

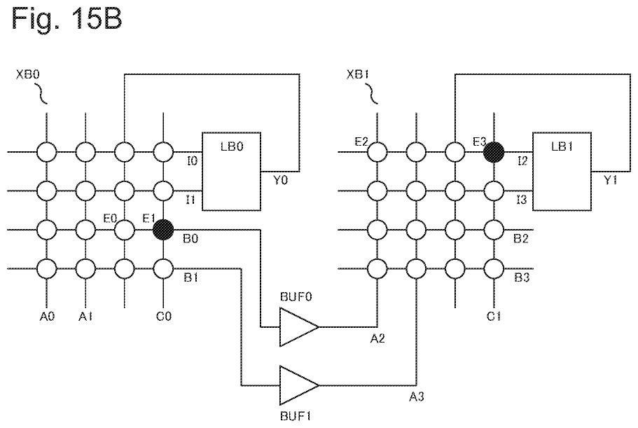

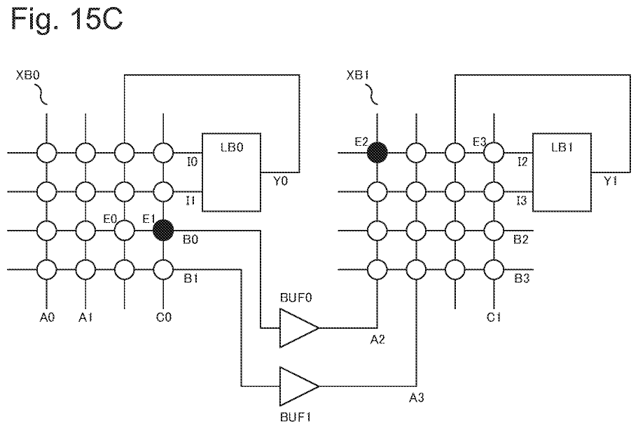

FIG. 15A is a schematic diagram illustrating one example of the programmable logic integrated circuit 401 on which the circuit A is mounted. FIG. 15B is a schematic diagram illustrating one example of the programmable logic integrated circuit 401 on which the circuit B is mounted based on configuration information. FIG. 15C is a schematic diagram illustrating one example of the programmable logic integrated circuit 401 when the circuit B is mounted based on revised configuration information after an equivalent circuit analysis.

With reference to FIG. 15A, a schematic diagram illustrating two logic blocks and a wiring resource connecting the two logic blocks provided in the programmable logic integrated circuit 401 is illustrated. The logic block as a logical element includes two input terminals and one output terminal. The wiring resource illustrated in FIG. 15A is formed of two crossbar switches and two buffer circuits.

The crossbar switch is formed of four column wires extending in a column direction, four row wires extending in a row direction, and resistance change elements located at intersecting portions of the column wires and the row wires. The crossbar switch can connect or disconnect any wire of the column wires and any wire of the row wires by using the resistance change element.

A crossbar switch XB0 uses column wires A0 and A1 as input lines, connects a column wire Y0 to an output terminal of a logic block LB0, and grounds a column wire C0. The crossbar switch XB0 uses row wires I1 and I1 as output lines, and connects them to input terminals of the logic block LB0. The crossbar switch XB0 uses row wires B0 and B1 as output wires, and connects them to input terminals of buffer circuits BUF0 and BUF1, respectively.

A crossbar switch XB1 uses column wires A2 and A3 as input lines, and connects them to output terminals of the buffer circuits BUF0 and BUF1, respectively. The crossbar switch XB1 connects a column wire Y1 to an output terminal of a logic block LB1, and grounds a column wire Cl. The crossbar switch XB1 uses row wires 12 and 13 as output lines, and connects them to input terminals of the logic block LB1. The crossbar switch XB1 uses row wires B2 and B3 as output wires.

As illustrated in FIG. 15A, the programmable logic integrated circuit 401 is successively wired, as the wiring route 1, the wire Y0, the resistance change element E0, the wire B0, the buffer circuit BUF0, the wire A2, the resistance change element E2, and the wire 12. The resistance change elements E0 and E2 are set in low resistance states, and conduct signals.

As illustrated in FIG. 15B, the programmable logic integrated circuit 401, when the circuit B is mounted based on the configuration information, is successively wired the wire C0, the resistance change element E1, the wire B0, the buffer circuit BUF0, and the wire A2, as a wiring route 2. Furthermore, the programmable logic integrated circuit 401 is successively wired the wire Cl, the resistance change element E3, and the wire 12. The wiring resistance change elements E1 and E3 are set in low resistance states, and conduct signals. The wires C0 and Cl are grounded, and the wires B0 and 12 are not used for propagation of a signal in the circuit B. When the wiring route 1 is changed to the wiring route 2, there occurs a reset operation of changing two bits of the resistance change elements E0 and E2 from low resistance states to high resistance states, and a set operation of changing two bits of the resistance change elements E1 and E3 from high resistance states to low resistance states.

As illustrated in FIG. 15C, the programmable logic integrated circuit 401, when the circuit B is mounted based on the revised configuration information after the equivalent circuit analysis, is successively wired the wire C0, the resistance change element E1, the wire B0, the buffer circuit BUF0, the wire A2, the resistance change element E2, and the wire 12, as a wiring route 3. The resistance change elements E1 and E2 are set in low resistance states, and conduct signals. The wire C0 is grounded, and the wires B0 and 12 are not used for propagation of a signal in the circuit B. When the wiring route 1 is changed to the wiring route 3, there occurs a reset operation of changing one bit of the resistance change element E0 from a low resistance state to a high resistance state and a set operation of changing one bit of the resistance change element E1 from a high resistance state to a low resistance state occur. Therefore, the wiring route 3 can reduce unnecessary rewriting of a resistance change element as compared with the wiring route 2.

Note that, in the description above, it is performed to select an optimum equivalent circuit based on a total number of resistance change elements in which rewriting occurs, but it may be performed to select an optimum equivalent circuit based on an abrasion cost of a resistance change element in which rewriting occurs. Further, in the description above, a target of optimization performed by analyzing an equivalent circuit is a wiring resource, but a don't-care-bit of a logic block may also be a target.

As described above, the design assistance system for assisting in designing a circuit mounted on the programmable logic integrated circuit 401 including a resistance change element according to the present example embodiment can level rewriting of the resistance change element of the programmable logic integrated circuit 401. Furthermore, the equivalent-circuit analysis tool 152 analyzes an equivalent circuit, based on configuration information being already mounted on the programmable logic integrated circuit 401 and configuration information output from the arrangement-and-wiring tool 132, and performs optimization in such a way as to reduce unnecessary rewriting. Therefore, the design assistance system can reduce unnecessary rewriting of a resistance change element.

The preferable example embodiments of the present invention have been described, but the present invention is not limited to the example embodiments. Various modifications can be made within the scope of the invention described in claims, and it is needless to say that the modifications are also included in the scope of the invention. For example, a part of resistance change elements included in the programmable logic integrated circuit may be replaced with another memory element such as an SRAM. Further, a part of resistance change elements included in a programmable logic integrated circuit may be replaced with a circuit in which a pass transistor is combined with another memory element such as an SRAM. Further, each function (processing) is described by assigning to each component, but the assignment is not limited to that mentioned above. Further, the above-mentioned example embodiments are also merely an example for a configuration of a component, which are not limited thereto.

Processing performed by each component provided in the above-mentioned design assistance system may be performed by logic circuits being respectively manufactured according to purposes. Further, a computer program (hereinafter referred to as a program) in which a processing content is described as a procedure may be recorded in a recording medium readable by the design assistance system, and the program recorded in the recording medium may be read and executed by the design assistance system. The recording medium readable by the design assistance system refers to, as well as a removable recording medium such as a floppy (®) disc, a magneto-optical disc, a digital versatile disc (DVD), a compact disc (CD), and a Blu-ray (®) disc, a memory such as a read only memory (ROM) and a random access memory (RAM) that are built in the design assistance system, a hard disc drive (HDD), and the like. A program recorded in the recording medium is read in a CPU provided in the design assistance system, and processing similar to that mentioned above is performed by control of the CPU. Herein, the CPU is operated as a computer that executes a program read from the recording medium in which the program is recorded.

The whole or part of the exemplary embodiments disclosed above can be described as, but not limited to, the following supplementary notes.

### (Supplementary Note 1)

A design assistance system that assists in designing a circuit to be mounted on a programmable logic integrated circuit including a resistance change element, the design assistance system includes:

rewriting-history-information generation means for generating rewriting history information indicating a number of changing times of a state of the resistance change element;

abrasion-cost generation means for calculating an abrasion cost of a switch included in the circuit, based on the rewriting history information; and

wiring means for carrying out wiring of the circuit, based on an evaluation function including the abrasion cost.

### (Supplementary Note 2)

The design assistance system according to supplementary note 1, wherein

the abrasion-cost generation means calculates the abrasion cost by using an abrasion cost function F(N) with respect to a number N of rewriting times being the number of changing times, and

the abrasion cost function includes an increasing section.

### (Supplementary Note 3)

The design assistance system according to supplementary note 1, wherein

the abrasion-cost generation means calculates the abrasion cost by using an abrasion cost function F(N) with respect to a number N of rewriting times being the number of changing times, and

the abrasion cost function is a function being a convexity in a downward direction and includes an increasing section.

### (Supplementary Note 4)

The design assistance system according to supplementary note 1, wherein

the abrasion-cost generation means calculates the abrasion cost by using an abrasion cost function F(N) with respect to a number N of rewriting times being the number of changing times, and

the abrasion cost function includes a section that changes in a step-like form.

### (Supplementary Note 5)

The design assistance system according to any one of supplementary notes 1 to 4, wherein

the abrasion-cost generation means or the wiring means sets a threshold number of times, according to at least one piece of information among
a number of times configuration is performed on the programmable logic integrated circuit,
a position of the resistance change element in the programmable logic integrated circuit,
a number of resistance change elements that require rewriting for greater than a threshold number of times being a number of rewriting times in which the abrasion cost changes in a step-like form,
whether or not the wiring is enabled, and
a delay time.

### (Supplementary Note 6)

The design assistance system according to any one of supplementary notes 1 to 5, wherein

the wiring means carries out wiring, based on an evaluation function including a delay cost and a congestion cost in addition to the abrasion cost.

### (Supplementary Note 7)

The design assistance system according to any one of supplementary notes 1 to 6, wherein

the abrasion-cost generation means calculates the abrasion cost by using an abrasion cost function F(N) with respect to a number N of rewriting times being the number of changing times, and

the abrasion cost function is a rate of failures of the resistance change element, or a value in which a rate of failures is scaled to a value comparable with a delay cost or a congestion cost.

### (Supplementary Note 8)

The design assistance system according to any one of supplementary notes 1 to 7, further includes

arrangement means for calculating a congestion cost, based on the abrasion cost, and performs arrangement of the resistance change element, based on an evaluation function including the congestion cost.

### (Supplementary Note 9)

The design assistance system according to any one of supplementary notes 1 to 8, further includes

equivalent-circuit analysis means for

counting a total number of resistance change elements in which rewriting occurs when the first configuration information is changed to the second configuration information, as a first count number, based on first configuration information being already mounted on the programmable logic integrated circuit and second configuration information in which the wiring means has carried out wiring,

generating third configuration information equivalent to the second configuration information,

counting a total number of resistance change elements in which rewriting occurs when the first configuration information is changed to the third configuration information, as a second count number, based on the first configuration information and the third configuration information, and

outputting the third configuration information when the second count number is less than the first count number.

### (Supplementary Note 10)

A design assistance method of assisting in designing a circuit to be mounted on a programmable logic integrated circuit including a resistance change element, the design assistance method includes:

generating rewriting history information indicating a number of changing times of a state of the resistance change element;

calculating an abrasion cost of a switch included in the circuit, based on the rewriting history information; and

carrying out wiring of the circuit, based on an evaluation function including the abrasion cost.

### (Supplementary Note 11)

The design assistance system according to any one of supplementary notes 1 to 9, further includes

a display device that displays information about the number of changing times or the abrasion cost.

### (Supplementary Note 12)

The design assistance system according to any one of supplementary notes 1 to 9, further includes

an input and output device capable of setting the abrasion cost.

The present invention has been described above by taking the above-mentioned example embodiments as exemplary examples. However, the present invention is not limited to the above-mentioned example embodiments. In other words, various aspects apparent to those skilled in the art may be applied to the present invention within the scope of the present invention.

This application is based upon and claims the benefit of priority from Japanese patent application No. 2017-011975, filed on Jan. 26, 2017, the disclosure of which is incorporated herein in its entirety by reference.

### REFERENCE SIGNS LIST

101, 102 Design assistance tool group
110 Rewriting-history-information generation unit
111, 112 Rewriting-history-information generation tool
120 Abrasion-cost generation unit
121, 122 Abrasion-cost generation tool
130 Wiring unit
131, 132 Arrangement-and-wiring tool
141, 142 Logical synthesis tool
152 Equivalent-circuit analysis tool
201 Design assistance system
211 Arithmetic device
221 Storage device
231 Display device
241 Input and output device
251 Bus
301 Configuration-information transfer device
401 Programmable logic integrated circuit

What is claimed is:

1. A design assistance system that assists in designing a circuit to be mounted on a programmable logic integrated circuit including a resistance change element, the design assistance system comprising:
a memory; and
at least one processor coupled to the memory,
the processor performing operations, the operations comprising:
generating rewriting history information indicating a number of changing times of a state of the resistance change element;
calculating an abrasion cost of a switch included in the circuit, based on the rewriting history information; and
carrying out wiring of the circuit, based on an evaluation function including the abrasion cost.

2. The design assistance system according to claim 1, wherein the operations further comprises
calculating the abrasion cost by using an abrasion cost function F(N) with respect to a number N of rewriting times being the number of changing times, wherein
the abrasion cost function includes an increasing section.

3. The design assistance system according to claim 1, wherein the operations further comprises
calculating the abrasion cost by using an abrasion cost function F(N) with respect to a number N of rewriting times being the number of changing times, wherein
the abrasion cost function is a function being a convexity in a downward direction and includes an increasing section.

4. The design assistance system according to claim 1, wherein the operations further comprises
calculating the abrasion cost by using an abrasion cost function F(N) with respect to a number N of rewriting times being the number of changing times, wherein
the abrasion cost function includes a section that changes in a step-like form.

5. The design assistance system according to claim 1, wherein the operations further comprises
setting a threshold number of times, according to at least one piece of information among
a number of times configuration is performed on the programmable logic integrated circuit,
a position of the resistance change element in the programmable logic integrated circuit,
a number of resistance change elements that require rewriting for greater than a threshold number of times being a number of rewriting times in which the abrasion cost changes in a step-like form,
whether or not the wiring is enabled, and
a delay time.

6. The design assistance system according to claim 1, wherein the operations further comprises
carrying out wiring, based on an evaluation function including a delay cost and a congestion cost in addition to the abrasion cost.

7. The design assistance system according to claim 1, wherein the operations further comprises
calculating the abrasion cost by using an abrasion cost function F(N) with respect to a number N of rewriting times being the number of changing times, wherein
the abrasion cost function is a rate of failures of the resistance change element, or a value in which a rate of failures is scaled to a value comparable with a delay cost or a congestion cost.

8. The design assistance system according to claim 1,
wherein the operations further comprises
calculating a congestion cost, based on the abrasion cost, and performs arrangement of the resistance change element, based on an evaluation function including the congestion cost.

9. The design assistance system according to claim 1,
wherein the operations further comprises
counting a total number of resistance change elements in which rewriting occurs when the first configuration information is changed to the second configuration information, as a first count number, based on first configuration information being already mounted on the programmable logic integrated circuit and second configuration information in which the wiring has carried out,
generating third configuration information equivalent to the second configuration information,
counting a total number of resistance change elements in which rewriting occurs when the first configuration information is changed to the third configuration information, as a second count number, based on the first configuration information and the third configuration information, and
outputting the third configuration information when the second count number is less than the first count number.

10. A design assistance method of assisting in designing a circuit to be mounted on a programmable logic integrated circuit including a resistance change element, the design assistance method comprising:
generating rewriting history information indicating a number of changing times of a state of the resistance change element;
calculating an abrasion cost of a switch included in the circuit, based on the rewriting history information; and
carrying out wiring of the circuit, based on an evaluation function including the abrasion cost.

11. The design assistance system according to claim 1, further comprising
a display device that displays information about the number of changing times or the abrasion cost.

12. The design assistance system according to claim 1, further comprising
an input and output device capable of setting the abrasion cost.
